(19) United States
(12) Patent Application Publication
(10) Pub. No.: US 2002/0094706 A1
(43) Pub. Date: Jul. 18, 2002

(54) Apparatus for interconnecting components in a thin profile computer system

(76) Inventors: James Britton, Half Moon Bay, CA (US); Thomas Yu, San Jose, CA (US); Greg Jones, San Francisco, CA (US)

Correspondence Address: Noreen Krall, Sun Microsystems, Inc., MS PAL01-521, 901 San Antonio Road, Palo Alto, CA, 94303-4900, US

(21) Appl. No.: 09/764,529

(22) Filed: Jan. 17, 2001

(51) Int. Cl. H05K 1/00

(52) U.S. Cl. 439/74

(57) ABSTRACT

An interconnection apparatus for a computer system. The apparatus includes a printed circuit board and a first connector coupled to the printed circuit board to receive a component. The component is disposed substantially parallel to the printed circuit board when the component is connected to the first connector. The printed circuit board may be connected to a motherboard of the computer system such that the printed circuit board is disposed substantially parallel to the motherboard.

### BACKGROUND OF THE INVENTION

1. Field of the Invention

The present invention relates to an interconnection apparatus for components in a computer system.

2. Background Information

A general purpose computer system often has numerous components which may be upgraded or replaced depending on what is required by users of the computer system. Typically, an important concern of users is the reliability of the computer system. Thus, if a component is no longer performing adequately or fails completely, the component will be replaced.

Certain computer systems, such as servers, are required to be highly reliable because they are used by many different users at varying times during the day and night. Thus, servers are often configured to facilitate the replacement of important components if such components fail. For example, it is common to make hard drives “hot-swappable” by allowing them to be accessed from the front of a server while the server is still running. A hard drive can then be replaced without causing any server down-time. In a typical server, a hot-swappable hard drive is plugged into a backplane which is vertically oriented relative to a motherboard of the server. The backplane has a connector which extends orthogonally from the backplane and receives the hard drive's connector.

FIGS. 1A and 1B illustrate a prior art system for interconnecting a component in a computer system, such as a server. A motherboard 102 of the computer system has connectors 104 which receive printed circuit boards 106. When boards 106 are plugged into connectors 104, boards 106 are orthogonal to motherboard 102. A connector 108 extends orthogonally from the vertically oriented surface of each board 106. A component 110, such as a hot-swappable hard drive, is plugged into connector 108. When component 110 is plugged into connector 108, component 110 is orthogonal to board 106. A case or chassis 100 forms the body of the computer system and encloses the circuitry and components of the computer system. The component 110 is located near the front 101 (e.g., the bezel) of case 100 such that the component 110 may be accessed. A fan 112 may be located on motherboard 102 to cool critical heat producing components (e.g., CPU).

Although FIGS. 1A and 1B show only one connector 108 on each board 106, it is common for an interconnection board to have more than one connector to allow more components to be added to the computer system. However, adding more connectors to a vertically oriented board, such as board 106, increases the height of the board which subsequently increases the height of the case required to enclose the board. Additionally, vertically oriented boards have limited surface area for circuitry and electronic components. Maintaining a thin profile is particularly important for servers that are stacked on top of one another in a rack environment. If additional single-connector boards are placed side-by-side across the motherboard, then air flow over the motherboard will be restricted.

Thus, it is desirable to add additional components to a computer system without enlarging the computer system's profile or impairing the air flow within the computer system.

### SUMMARY OF THE INVENTION

An interconnection apparatus for a computer system includes a printed circuit board and a first connector coupled to the printed circuit board. The first connector is engageable with a component such that the component is substantially parallel to the printed circuit board when the component is engaged with the first connector. The printed circuit board may be connected to a motherboard of the computer system such that the printed circuit board is substantially parallel to the motherboard.

Additional features and benefits of the present invention will become apparent from the detailed description, figures and claims set forth below.

### BRIEF DESCRIPTION OF THE DRAWINGS

Various embodiments of the present invention will be described in detail with reference to the following drawings. The present invention is illustrated by way of example and not limitation in the accompanying figures.

FIG. 1A illustrates an exploded perspective view of a prior art interconnection system.

FIG. 1B illustrates a side cutaway view of a computer system using the prior art interconnection system shown in FIG. 1A.

FIG. 2 illustrates an exploded perspective view of an interconnection apparatus in accordance with the teachings of the present invention.

FIG. 3 illustrates a perspective view of an interconnection apparatus having multiple components connected thereto in accordance with the teachings of the present invention.

FIG. 4 illustrates a side cutaway view of a computer system using an interconnection system in accordance with the teachings of the present invention.

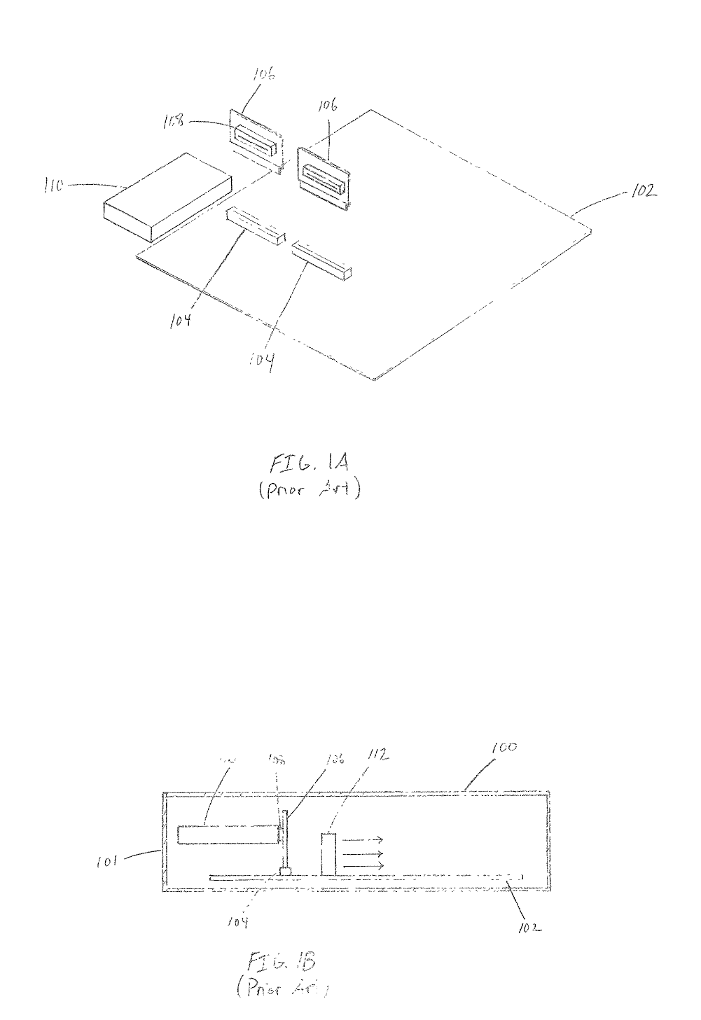

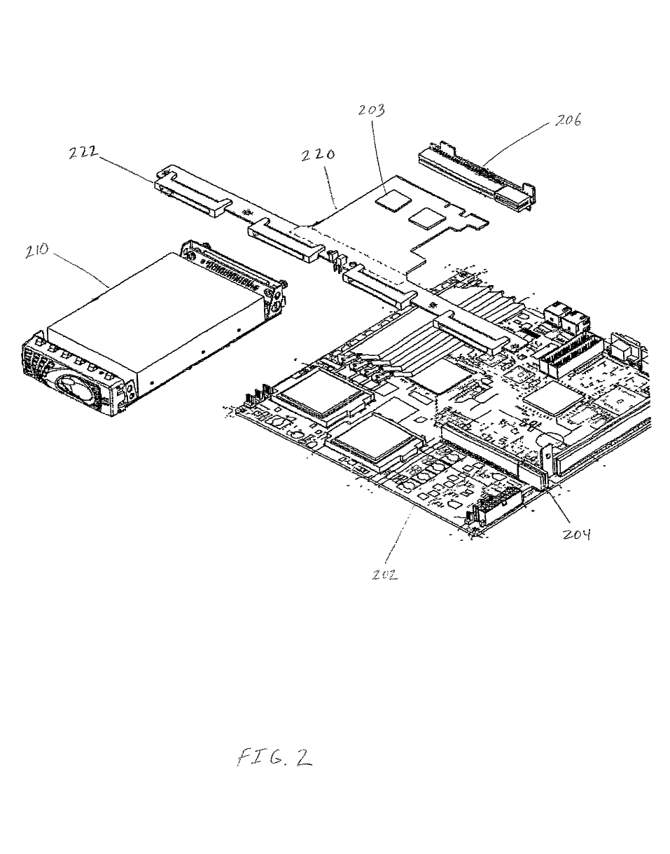

### DETAILED DESCRIPTION

The description and accompanying drawings are for purposes of illustration and are not to be used to construe the invention in a restrictive manner. In the following description, specific details are set forth, in order to provide a thorough understanding of the invention. However, it will be apparent to one of ordinary skill in the art that the invention can be practiced without these specific details. In other instances, well-known processing steps, methods, materials, etc. have not been described in particular detail in order to avoid unnecessarily obscuring the invention. The invention will be described with specific reference to thin profile server computer systems, but it is appreciated that the invention is not limited to any one field of use.

Thin profile servers are often used when floor space is limited. Typically, a number of thin profile servers are stacked on top of each other in a rack to take advantage of a room's vertical space. To take full advantage of a room's vertical space, some servers are sized with a 1 U (1.75 inch height) form factor. However, a 1 U form factor precludes the use of a vertically aligned interconnection board.

FIG. 2 illustrates an exploded perspective view of an interconnection apparatus according to the present invention. A motherboard 202 includes a connector 204 which receives an adapting connector 206. Motherboard 202 is disposed horizontally within the case (not shown) of a thin profile server. Connector 206 receives an interconnection board 220 (e.g., a printed circuit board) having several connectors 222 extending from an edge of board 220. Adjacent connectors 222 may be spaced apart from each other at equal intervals to allow similar components to be connected concurrently to connectors 222. A component 210, such as a hot-swappable hard drive, is plugged into one of the connectors 222. When component 210 is engaged with one of the connectors 222, component 210 is substantially parallel to board 220 and motherboard 202. Thus, board 220 is also substantially parallel to motherboard 202 when they are connected to each other via connectors 204 and 206.

It should be noted that board 220, connectors 222 and component 210 lie in the same plane when component 210 is plugged into one of the connectors 222. It should also be noted that board 220 includes circuitry 203 (e.g., hard drive controller circuitry) for running component 210. Because only one board 220 is needed in the interconnection system shown in FIG. 2, a different bus or interconnection standard may be supported by replacing a single board 220 rather than multiple boards. Thus, system interface flexibility is achieved. Furthermore, because connectors 222 are mounted on an edge of board 220 rather than on a flat surface of board 220, the interconnection system shown in FIG. 2 is useable within the confines of a thin profile server's form factor.

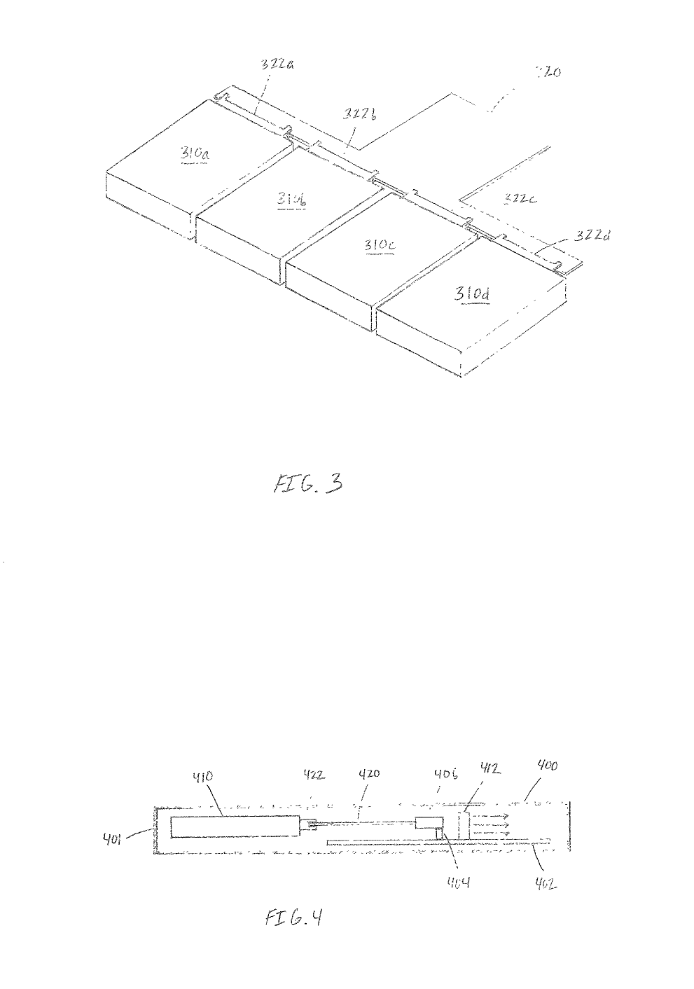

FIG. 3 illustrates a perspective view of an interconnection apparatus having multiple components connected thereto in accordance with the teachings of the present invention. An interconnection board 320 has connectors 322a, 322b, 322c, 322d extending from an edge of board 320. Components 310a, 310b, 310c, 310d are engaged with connectors 322a, 322b, 322c, 322d, respectively. Adjacent connectors are spaced apart from each other equally to accommodate similarly sized components 310a-310d side-by-side. When board 320 is oriented horizontally within a server chassis, components 310a-310d are also oriented horizontally when plugged into connectors 322a-322d, respectively. Because components 310a-310d, connectors 322a-322d and board 320 lie in the same horizontal plane, vertical space is saved.

FIG. 4 illustrates a side cutaway view of a computer system using an interconnection system according to the present invention. A motherboard 402 is disposed horizontally within a case or chassis 400 having a front bezel 401. A connector 404 coupled to motherboard 402 receives an adapting connector 406. Connector 406 is oriented toward bezel 401 to receive an interconnection board 420. When board 420 is engaged with connector 406, board 420 is oriented horizontally within chassis 400 and is parallel to motherboard 402. A connector 422 is coupled to and extends from an edge of board 420. Thus, connector 422 is aligned with board 420. It should be noted that connector 422 does not extend orthogonally from either main surface (top or bottom) of board 420. A component 410 is connected to connector 422 such that component 410 is also aligned with board 420. Because component 410 lies in the same horizontal plane as board 420 and no part of component 410 is located over board 420, the interconnection system shown in FIG. 4 maintains a thin profile within chassis 400.

A fan 412 located on motherboard 402 generates an airflow to help dissipate heat generated by the components (e.g., CPU) on motherboard 402. Because board 420 is oriented horizontally within chassis 400, a gap is located between the top of board 420 and the top inside surface of chassis 400. Thus, the orientation of board 420 facilitates the flow of air over board 420 and, subsequently, throughout the interior of chassis 400. Furthermore, board 420 may be formed in a “T-shape” such as that shown by board 320 in FIG. 3 in order to facilitate the flow of air below board 420.

In the foregoing detailed description, the present invention has been described with reference to specific exemplary embodiments. However, it will be evident that various modifications and changes may be made without departing from the broader scope and spirit of the present invention. The present specification and figures are accordingly to be regarded as illustrative rather than restrictive.

What is claimed is:

1. An interconnection apparatus for a computer system, the apparatus comprising:
a printed circuit board;
a first connector coupled to said printed circuit board to receive a component, wherein said component is substantially parallel to said printed circuit board when said component is coupled to said first connector.

2. The apparatus of claim 1, wherein said printed circuit board is couplable to a motherboard of the computer system such that said printed circuit board is substantially parallel to said motherboard.

3. The apparatus of claim 1, further comprising:
a second connector coupled to said printed circuit board;
a third connector coupled to said printed circuit board;
wherein said first, second and third connectors are oriented in a first direction.

4. The apparatus of claim 3, wherein said first connector is spaced apart from said second connector by a first distance and said second connector is spaced apart from said third connector by said first distance.

5. The apparatus of claim 1, wherein said first connector is coupled to an edge of said printed circuit board.

6. The apparatus of claim 5, wherein said component is not disposed over said printed circuit board when said component is coupled to said first connector.

7. An interconnection apparatus in a computer system, the apparatus comprising:
an interconnection board coupled to a motherboard of the computer system, wherein said interconnection board lies in a first plane and wherein said interconnection board and said motherboard are substantially parallel;
a plurality of connectors extending from an edge of said interconnection board, wherein a component engaged with one of said connectors lies in said first plane.

8. The apparatus of claim 7, wherein said component is a hot-swappable component.

9. The apparatus of claim 7, wherein said interconnection board has a top surface and said plurality of connectors are oriented non-orthogonally to said top surface.

10. The apparatus of claim 7, wherein said interconnection board is configured to facilitate an air flow within the computer system.

11. The apparatus of claim 7, wherein each of said connectors is engageable with a hot-swappable hard drive.

12. The apparatus of claim 7, wherein said interconnection board and said motherboard coupled together maintains a thin profile.

13. An interconnection system for a plurality of hot-swappable components in a thin profile server, the system comprising:
a horizontally oriented interconnection board coupled to a motherboard of the server, said interconnection board having a plurality of connectors extending from an edge of said interconnection board, each of said connectors engageable with one of the hot-swappable components, wherein the hot-swappable components lie in a common plane when engaged with said connectors.

14. The system of claim 13, wherein said connectors are aligned with said interconnection board.
